(19) United States
(12) Patent Application Publication
(10) Pub. No.: US 2026/0165125 A1
(43) Pub. Date: Jun. 11, 2026

(54) SEMICONDUCTOR PACKAGE AND METHOD FOR MANUFACTURING THE SAME

(71) Applicant: Samsung Electronics Co., Ltd., Suwon-si (KR)

(72) Inventor: DongWoon PARK, Suwon-si (KR)

(73) Assignee: Samsung Electronics Co., Ltd., Suwon-si (KR)

(21) Appl. No.: 19/182,079

(22) Filed: Apr. 17, 2025

(30) Foreign Application Priority Data
Sep. 25, 2024 (KR) 10-2024-0129781

(51) Int. Cl. H10W 40/20

(52) U.S. Cl. CPC H10W 40/242

(57) ABSTRACT

A semiconductor package according to some example embodiments includes: a substrate; a sub-semiconductor package on the substrate; a metal structure on the substrate and adjacent to the sub-semiconductor package, a bottom surface of the metal structure including a first region and a second region at least partially surrounding the first region, first region is recessed from the second region; a first thermal interface material between the substrate and the first region; and a second thermal interface material between the substrate and the second region.

### CROSS-REFERENCE TO RELATED APPLICATION

This application claims priority to and the benefit of Korean Patent Application No. 10-2024-0129781 filed in the Korean Intellectual Property Office on Sep. 25, 2024, the entire contents of which are incorporated herein by reference.

### BACKGROUND

### (a) Field

At least some example embodiments relate to a semiconductor package and/or to a manufacturing method thereof.

### (b) Description of the Related Art

In response to demands of the semiconductor industry, semiconductor packages are becoming lighter, thinner, miniaturized, faster, and/or more functional. As semiconductor packages become lighter, thinner, miniaturized, faster, and/or more multifunctional, the electric power per unit volume consumed by a semiconductor chip within the semiconductor package may increase, which in turn may increase heat generated by the semiconductor chip. When heat generated in the semiconductor chip is not released to the outside of the semiconductor package, such heat remains within the semiconductor package that includes the semiconductor chip, and a difference in thermal stress may occur within the semiconductor package structure, which may be related to warpage in the semiconductor package. Moreover, when the heat generated in the semiconductor chip is not released to the outside of the semiconductor package, the temperature of the semiconductor package may increase, and such an increase in temperature may affect the operation speed of the semiconductor chip, which may deteriorate the reliability of the product.

To address these problems, a metal structure formed of, for example, a metal material with higher thermal conductivity that may serve as or include a heat slug and/or a stiffener to aid in controlling warpage of the semiconductor package may be applied and used in the semiconductor package. Such a metal structure may be, for example, attached to a substrate by a thermal interface material (TIM).

However, although the metal structure may be attached to the substrate using the thermal interface material, a space that is not filled by the thermal interface material may be formed (for example, defined) between the substrate and the metal structure, and since this space that is not filled by the thermal interface material between the substrate and the metal structure may be formed randomly, it may be difficult to control it consistently, and thus deviations in the position at which the thermal interface material is attached may occur. It may also be difficult to apply additional thermal interface material to fill the space not filled by the initial thermal interface material because it may be difficult to specifically address a randomly formed (for example, defined) empty space. Moreover, using a relatively large amount of thermal interface material to remove(for example, fill or substantially fill) a space between the substrate and the metal structure that is not filled by the initial thermal interface material may cause thermal interface material to leak out of the metal structure. When a space not filled by the thermal interface material is formed between the substrate and the metal structure or when the thermal interface material leaks out of the metal structure, one of the more of these may worsen the warpage of the semiconductor package and/or deteriorate the mechanical characteristics of the semiconductor package.

In addition, when the thermal interface material positioned between the substrate and the metal structure is too thick, a thermal bottleneck phenomenon in the thermal interface material may become more severe, and the heat dissipation characteristics of the semiconductor package may be compromised or deteriorate. When the thermal interface material positioned between the substrate and the metal structure is too thin, a space not filled by the thermal interface material may be formed between the substrate and the metal structure, and the bonding reliability of the metal structure may be compromised or deteriorate.

### SUMMARY

Inventive concepts relate to, for example, semiconductor package in which thermal interface materials (TIMs) having different characteristics are placed between a substrate and a metal structure.

A semiconductor package according to some example embodiments may include a substrate; a sub-semiconductor package on the substrate; a metal structure on the substrate and adjacent to the sub-semiconductor package, a bottom surface of the metal structure including a first region and a second region at least partially surrounding the first region, the first region being recessed from the second region; a first thermal interface material between the substrate and the first region; and a second thermal interface material between the substrate and the second region.

A semiconductor package according to some example embodiments may include: substrate; a sub-semiconductor package on the substrate; a plurality of metal structures on the substrate and at least partially surrounding side surfaces of the sub-semiconductor package, a bottom surface of each of the plurality of metal structures including a first region and a second region at least partially surrounding the first region, the first region being recessed from the second region; a plurality of first thermal interface materials, each of the plurality of first thermal interface materials attaching the first region of a corresponding metal structure among the plurality of metal structures to the substrate and having a first thickness in a vertical direction; and a plurality of second thermal interface materials, each of the plurality of second thermal interface materials attaching the second region of a corresponding metal structure among the plurality of metal structures to the substrate and having a second thickness that is smaller than the first thickness in the vertical direction.

A semiconductor package manufacturing method may include: mounting a sub-semiconductor package on a substrate; applying a first thermal interface material on the substrate and adjacent to the sub-semiconductor package; attaching a metal structure to the first thermal interface material, a bottom surface of the metal structure including a first region and a second region around the first region, the first region being recessed from the second region, the first thermal interface material being attached to the first region; and inserting a second thermal interface material between the substrate and the second region of the metal structure.

The position of a relatively thick first thermal interface material attached to the metal structure can be fixed, thereby improving warpage of the semiconductor package.

A relatively thin second thermal interface material can be injected between the substrate and the metal structure by utilizing capillary action phenomena. Since the area of the space between the substrate and the metal structure that is not filled by the first thermal interface material, into which the second thermal interface material is to be injected, is specified, it is possible to inject a more exact amount of the second thermal interface material according to the area of the space between the substrate and the metal structure, thereby improving the bonding reliability of the metal structure and the reducing and/or limiting warpage of the semiconductor package.

The second thermal interface material in contact with the metal structure has a relatively thin thickness, and a thickness of a portion of the metal structure in contact with the second thermal interface material is relatively thick. Accordingly, the heat dissipation characteristics of the semiconductor package can be improved by the second thermal interface material having a relatively thin thickness and relatively a thick metal structure in contact with the second thermal interface material.

Depending on the product, the ratio of the first thermal interface material and the second thermal interface material can be designed differently to control the heat dissipation characteristics, mechanical reliability, and warpage of the semiconductor package for each product.

### BRIEF DESCRIPTION OF THE DRAWINGS

FIG. 1 is a cross-sectional view of a semiconductor package according to some example embodiments.

FIG. 2 is a top plan view of the semiconductor package according to some example embodiments, taken along the line A-A of FIG. 1.

FIG. 3 is a top plan view of a semiconductor package according to some example embodiments, taken along the line B-B of FIG. 1.

FIG. 4 is a perspective view that illustrates a metal structure and thermal interface materials in the region R1 of FIG. 2 and FIG. 3.

FIG. 5 is a top plan view of a semiconductor package according to some example embodiments, taken along the line A-A of FIG. 1.

FIG. 6 is a top plan view of the semiconductor package according to some example embodiments, taken along the line B-B of FIG. 1.

FIG. 7 is a perspective view of a metal structure and thermal interface materials in the region R2 of FIG. 5 and FIG. 6.

FIG. 8 is a top plan view of a semiconductor package according to some example embodiments, taken along the line A-A of FIG. 1.

FIG. 9 is a top plan view of the semiconductor package according to some example embodiments, taken along the line B-B of FIG. 1.

FIG. 10 is a perspective view of a metal structure and thermal interface materials in the region R3 of FIG. 8 and FIG. 9.

FIG. 11 is a cross-sectional view of a semiconductor package according to some example embodiments.

FIG. 12 to FIG. 19 are cross-sectional views provided for description of a method for manufacturing the semiconductor package of FIG. 1.

### DETAILED DESCRIPTION

Hereinafter, various embodiments of inventive concepts will be described in detail with reference to the attached drawings such that a person having ordinary skill in the art to which the inventive concepts pertain can easily implement the invention. The inventive concepts may be implemented in many different forms and are not limited to the example embodiments described herein.

In order to clearly explain the inventive concepts, parts that are not related to the description are omitted, and the same or similar reference symbols are used for identical or similar components throughout the specification.

In addition, the size and thickness of each component shown in the drawing are arbitrarily shown for better understanding and ease of description, so the present disclosure is not necessarily limited to what is shown.

Throughout this specification and the claims that follow, when it is described that an element is “connected” to another element, this includes not only cases where it is “directly connected” but also cases where it is “indirectly connected” through another member. In addition, unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, throughout the specification, the word “on” a target element will be understood to be positioned above or below the target element, and will not necessarily be understood to be positioned “at an upper side” based on an opposite to gravity direction.

Further, throughout the specification, the phrase “on a plane” means viewing a target portion from the top, and the phrase “on a cross-section” means viewing a cross-section formed by vertically cutting a target portion from the side.

Hereinafter, referring to the accompanying drawings, a semiconductor package 100 and a manufacturing method thereof according to some example embodiments will be described.

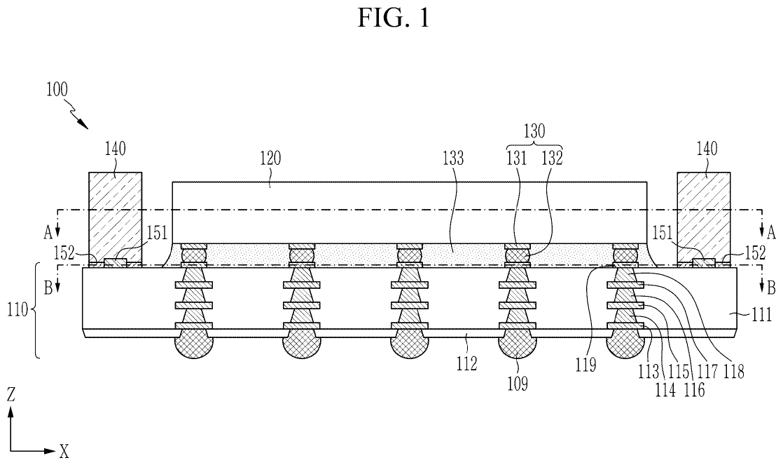

FIG. 1 is a cross-sectional view of a semiconductor package 100 according to some example embodiments.

Referring to FIG. 1, a semiconductor package 100 may include a substrate 110, a sub-semiconductor package 120, a bump structures 130, an underfill member 133, a metal structure 140, a first thermal interface material 151, and a second thermal interface material 152. In some example embodiments, the semiconductor package 100 may be manufactured based on, for example, a fan-out wafer level package (FOWLP) or fan-out panel level package (FOPLP) method, but example embodiments are not limited thereto.

The substrate 110 may include connection members 109, a substrate base 111, an insulation member 112, and a wiring pattern structures 113 to 119. The substrate 110 has a sub-semiconductor package 120 and a metal structure 140 mounted on an upper surface thereof, and may support the sub-semiconductor package 120 and the metal structure 140. The substrate 110 may be electrically connected to an external device and the sub-semiconductor package 120. In some example embodiments, the substrate 110 may include, for example, a printed circuit board (PCB), but example embodiments are not limited thereto. In some example embodiments, the substrate 110 may include, for example, an embedded trace substrate (ETS) having a coreless form in which a core layer is removed. In some example embodiments, the substrate 110 may include, for example, a glass substrate, a silicon interposer, a redistribution interposer, and/or a composite interposer, but example embodiments are not limited thereto.

The connection members 109 may be arranged on a bottom surface of the substrate base 111. Any or each of the connection members 109 may be disposed within a corresponding through opening of through openings of (for example, defined by) the insulation member 112. Each of the connection members 109 may be placed beneath a corresponding first wiring line 113 of first wiring lines 113. Any or each of the connection members 109 may electrically connect a corresponding first wiring line 113 of the first wiring lines 113 to an external device. Any or each of the connection members 109 may route a signal and/or electric power transmitted to the sub-semiconductor package 120, or may route a signal and/or electric power transmitted from the sub-semiconductor package 120. In some example embodiments, the connection members 109 may include, for example, solder balls and/or bumps. In some example embodiments, the connection members 109 may be, for example, arranged with a grid array, such as a pin grid array, a ball grid array, or a land grid array.

The substrate base 111 may include wiring pattern structures 113 to 118 therein, excluding bonding pads 119. The substrate base 111 may protect and/or insulate the wiring pattern structures 113 to 118. The bonding pads 119, the underfill member 133, the first thermal interface material 151, and the second thermal interface material 152 may be arranged on an upper surface of the substrate base 111. The insulation member 112 and the connection members 109 may be arranged on the bottom surface of the substrate base 111.

The substrate base 111 may include, for example, a copper foil laminate or a shape in which a wiring layer is additionally laminated on the cross-section or both side surfaces of the copper foil laminate, but example embodiments are not limited thereto. The substrate base 111 may include a dielectric. In some example embodiments, the dielectric may include, for example, a thermosetting resin such as an epoxy resin, a thermoplastic resin such as a polyimide, or a material comprising these resins mixed with inorganic fillers, but example embodiments are not limited thereto. In some example embodiments, the dielectric may include, for example, a resin impregnated/immersed in a core material such as glass fiber (glass fiber, glass cloth, glass fabric), or a material in which these resins are mixed with inorganic fillers, but example embodiments are not limited thereto. In some example embodiments, the dielectric may include a prepreg, Ajinomoto build-up film (ABF), FR-4, and/or bismaleimide triazine (BT). In some example embodiments, the dielectric may include a photoimageable dielectric (PID). In some example embodiments, the dielectric may include a silicon material and/or a glass material.

The insulation member 112 may be placed on the bottom surface of the substrate base 111. The insulation member 112 may include through openings for, for example, soldering. Any or each of the through openings of the insulation member 112 may have a corresponding connection member 109 of the connection members 109 disposed within it. The insulation member 112 may surround or at least partially surround a portion of each side of connection members 109. The insulation member 112 may protect the wiring pattern structures 113 to 118 and limit or prevent the connection members 109 from being shorted to each other. In some example embodiments, the insulation member 112 may include, for example, a solder resist, but example embodiments are not limited thereto.

The wiring pattern structures 113 to 119 may include first wiring lines 113, first wiring vias 114, second wiring lines 115, second wiring vias 116, third wiring lines 117, third wiring vias 118, and the bonding pads 119. The first wiring lines 113, the first wiring vias 114, the second wiring lines 115, the second wiring vias 116, the third wiring lines 117, and the third wiring vias 118 may be disposed in the substrate base 111. The bonding pads 119 may be arranged on the upper surface of the substrate base 111. The first wiring lines 113, the second wiring lines 115, and the third wiring lines 117 may extend in the X direction (horizontal direction) within the substrate base 111. The first wiring vias 114, the second wiring vias 116, and the third wiring vias 118 may extend in the Z direction (vertical direction) within the substrate base 111.

The first wiring lines 113, the first wiring vias 114, the second wiring lines 115, the second wiring vias 116, the third wiring lines 117, the third wiring vias 118, and the bonding pads 119 may be arranged sequentially from below and may be electrically connected to each other. In some example embodiments of FIG. 1, the wiring pattern structures 113 to 119 include three layers of vias, but in other embodiments, wiring pattern structures 113 to 119 may include fewer or greater numbers of wiring layers and vias and this may be included within the scope of the present disclosure. In some example embodiments, the first wiring lines 113, the first wiring vias 114, the second wiring lines 115, the second wiring vias 116, the third wiring lines 117, the third wiring vias 118, and the bonding pads 119 each may include, for example, at least one of copper, aluminum, silver, tin, gold, nickel, lead, titanium, and any alloys thereof, but example embodiments are not limited thereto.

The sub-semiconductor package 120 may be disposed on the substrate 110. The sub-semiconductor package 120 may be provided in plurality. In some example embodiments, the sub-semiconductor package 120 may include, for example, a 3-dimensional integrated circuit (3DIC) structure, a 2.5D semiconductor package, a 3D semiconductor package, a package on package (PoP), a chip stacking package, or a system in package (SiP), but example embodiments are not limited thereto. The sub-semiconductor package 120 may include at least one of a logic die, a memory die, and an interposer, but example embodiments are not limited thereto. The sub-semiconductor package 120 [symbol] may include a system on chip (SoC), an application processor (AP), or a high bandwidth memory (HBM), but example embodiments are not limited thereto.

The bump structures 130 may be disposed between the substrate 110 and the sub-semiconductor package 120. The bump structures 130 may electrically connect the sub-semiconductor package 120 to the substrate 110. Any or of the bump structures 130 may include a filler 131 and a solder 132. In some example embodiments, the filler 131 may include, for example, at least one of copper, aluminum, silver, tin, gold, nickel, lead, titanium, and any alloys thereof, but example embodiments are not limited thereto. In some example embodiments, solder 132 may include, for example, at least one of tin, silver, lead, nickel, copper, and any alloys thereof, but example embodiments are not limited thereto.

The underfill member 133 may be disposed between the substrate 110 and the sub-semiconductor package 120. The underfill member 133 may surround (for example, at least partially surround), protect, and/or insulate the bonding pads 119 and the bump structures 130. In some example embodiments, the underfill member 133 may include, for example, a non-conductive film (NCF), a non-conductive paste (NCP), and/or a molded underfill (MUF), but example embodiments are not limited thereto.

The metal structure 140 may be disposed on an upper surface of the substrate 110. The metal structure 140 may be arranged next to (for example, adjacent to) the sub-semiconductor package 120. The metal structure 140 may be arranged to surround (for example, at least partially surround) side surfaces of the sub-semiconductor package 120. The metal structure 140 may be separated (for example, spaced apart from) from the sub-semiconductor package 120. The metal structure 140 may have a height that is the same level as the level of the upper surface of the sub-semiconductor package 120, a level lower than the level of the upper surface of the sub-semiconductor package 120, or a level higher than the level of the upper surface of the sub-semiconductor package 120. The metal structure 140 may be electrically isolated from the substrate 110 and from the sub-semiconductor package 120. The metal structure 140 may be thermally connected to the substrate 110. In some example embodiments, the metal structure 140 may include a conductive material having higher thermal conductivity. In some example embodiments, the metal structure 140 may include at least one of copper, aluminum, silver, tin, gold, nickel, lead, titanium, and any alloys thereof, but example embodiments are not limited thereto.

The metal structure 140 may be attached to the substrate 110 by thermal interface materials having different thicknesses. The metal structure 140 may be attached to the substrate 110 by a first thermal interface material 151 and a second thermal interface material 152 having a thinner thickness than the first thermal interface material 151. A bottom surface of the metal structure 140 may include a recessed portion for accommodating the first thermal interface material 152 having a thickness thicker than the second thermal interface material 152. The recessed portion of the metal structure 140 may be a trench formed (for example, defined) in the Z-axis direction (vertical direction) with the bottom surface of the metal structure 140 as a reference. In some example embodiments, a cross-section of the trench may have the shape of a V, a quadrangle, a circle, an ellipse, or a polygon, but example embodiments are not limited thereto. In some example embodiments, one plane of the trench may have the shape of a quadrangle, circle, ellipse, or polygon, but example embodiments are not limited thereto.

The metal structure 140 may be or include a stiffener that can control the warpage of the semiconductor package 100. The metal structure 140 may be or include a heat dissipation structure that emits heat generated from the sub-semiconductor package 120. In some example embodiments, the metal structure 140 may include a heat slug, a heat sink, or a heat spreader. Some of the heat generated in the sub-semiconductor package 120 may be transferred to the metal structure 140 through the substrate 110, the first thermal interface material 151, and the second thermal interface material 152. The metal structure 140 may release received heat to the outside.

The metal structure 140 may be attached to the substrate 110 using a thermal interface material (TIM). The thermal interface material is interposed between the substrate 110 where heat is generated and retained and the metal structure 140 that releases heat, thereby improving thermal coupling between the substrate 110 and the metal structure 140. Thermal interface material may fill or at least partially fill an air layer of a contacting surface (for example, region) between the substrate 110 and the metal structure 140 to reduce thermal contact resistance.

The thermal interface material that attaches (for example, that may be used to attach) the metal structure 140 to the substrate 110 may include the first thermal interface material 151 and the second thermal interface material 152 that is different from the first thermal interface material 151. A thickness of the second thermal interface material 152 in the Z-axis direction (vertical direction) may be thinner than a thickness of the first thermal interface material 151 in the Z-axis direction (vertical direction). The first thermal interface material 151 and the second thermal interface material 152 may be disposed between the substrate 110 and the metal structure 140. The first thermal interface material 151 and the second thermal interface material 152 may be placed next (for example, adjacent to) to the sub-semiconductor package 120. The first thermal interface material 151 and the second thermal interface material 152 may be arranged to surround or at least partially surround side surfaces of the sub-semiconductor package 120. The first thermal interface material 151 and the second thermal interface material 152 may be separated (for example, spaced apart) from the sub-semiconductor package 120. The first thermal interface material 151 and the second thermal interface material 152 may be thermally connected to the substrate 110 and to the metal structure 140. The first thermal interface material 151 and the second thermal interface material 152 may attach (for example, be used to attach) the metal structure 140 to the substrate 110.

The first thermal interface material 151 and the second thermal interface material 152 each may be or include a composite material including at least one of a thermosetting resin, conductive filler, a hardener, a catalyst, or a thermoplastic resin. The first thermal interface material 151 and the second thermal interface material 152 may differ from each other in (for example, with respect to) at least one of a material of the thermosetting resin, a material of the conductive filler, a material of the hardener, a material of the catalyst, a material of the thermoplastic resin, the size (for example, particle size or average particle size) of the conductive filler, and the content of the conductive filler.

The first thermal interface material 151 may include a first thermosetting resin. The second thermal interface material 152 may include a second thermosetting resin. The second thermosetting resin may include a material that is the same as or different from a material of the first thermosetting resin. The first thermosetting resin and the second thermosetting resin may be selected from materials having suitable thermal and/or mechanical characteristics as thermal interface materials. In some example embodiments, the first thermosetting resin and the second thermosetting resin each may at least one include polysiloxane resin, epoxy resin, phenoxy resin, bismaleimide resin, acryl resin, unsaturated polyester, urethane, urea, phenol-formaldehyde, vulcanized rubber, melamine resin, polyimide, epoxy novolac resin, diglycidyl ether of bisphenol A (DGEBA), or cyanate ester, but example embodiments are not limited thereto.

The first thermal interface material 151 may include a first conductive filler. The second thermal interface material 152 may include a second conductive filler. The second conductive filler may comprise a material that is the same as or different from a material of the first conductive filler. The second thermal interface material 152 may not include a conductive filler. In some example embodiments, the first conductive filler and the second conductive filler each may include, for example, metal particles or metal oxide particles (for example, a material comprising metal particles and/or metal oxide particles). For example, in some example embodiments, the first conductive filler and the second conductive filler may each include at least one of alumina, silica, titania, aluminum, nitride aluminum, boron nitride, zinc oxide, silver, and/or silver-coated copper.

The first conductive filler may comprise a material having relatively excellent or desired heat transfer characteristics. The second conductive filler may include a material having at least one of relatively excellent or desired heat transfer characteristics and relatively low or desired viscosity characteristics. The first conductive filler may have a thermal conductivity greater than the thermal conductivity of the second conductive filler. In some example embodiments, for example, the first conductive filler may have a thermal conductivity in a range of about 1 W/mK to 300 W/mK, and, for example, some example embodiments the second conductive filler may have a thermal conductivity in a range of about 0.1 W/mK to 50 W/mK. Accordingly, the first thermal interface material 151 including the first conductive filler may have a first thermal conductivity, the second thermal interface material 152 including the second conductive filler may have a second thermal conductivity, and the first thermal conductivity may be greater than the second thermal conductivity. The first thermal interface material 151 including the first conductive filler may have a first thermal resistance, and the second thermal interface material 152 including the second conductive filler may have a second thermal resistance, and the first thermal resistance may be smaller than the second thermal resistance.

The first conductive filler may have a size (for example, particle size or average particle size) and content suitable for improving heat transfer characteristics. The second conductive filler may have a size and content suitable for improving heat transfer characteristics and fluidity. The first conductive filler has a first size, the second conductive filler has a second size, and the first size may be larger than the second size. In some example embodiments, the first conductive filler may have a size ranging from about 50 nm to about 100 μm, but example embodiments are not limited thereto. In some example embodiments, the second conductive filler may have a size ranging from about 50 nm to about 50 μm, but example embodiments are not limited thereto. The first conductive filler has a first content, the second conductive filler has a second content, and the first content may be greater than the second content. In some example embodiments, the first conductive filler may have, for example, a content in a range of about 40 wt % to about 80 wt %, with the total weight of the first thermal interface material 151 as a reference, but example embodiments are not limited thereto. In some example embodiments, the second conductive filler may have an amount in a range of about 20 wt % to about 60 wt %, with the total weight of the second thermal interface material 152 as a reference, but example embodiments are not limited thereto.

A hardener may be added to a thermosetting resin to harden the thermosetting resin. The hardener may be added to control the degree of hardening of the thermosetting resin. The mechanical characteristics of each of the first thermal interface material 151 and the second thermal interface material 152 may be controlled or modified by adding the hardener to the thermosetting resin. In some example embodiments, the hardener may include, for example, at least one of an amine compound, an acid anhydride compound, an amide compound, an imidazole compound, and a phenol compound, but example embodiments are not limited thereto.

A catalyst may be added to the thermosetting resin to control or modify a curing rate of the thermosetting resin. The curing rate of the thermosetting resin may be controlled or modified by adjusting the catalyst content and/or by using a catalyst that slows down the curing rate. In some example embodiments, the catalyst may include, for example, at least one of a phosphorus compound, a boron compound, a phosphorus-boron compound, or an imidazole compound, but example embodiments are not limited thereto.

A thermoplastic resin may be added to the thermosetting resin to impart fluidity to the thermosetting resin. The thermoplastic resin may be included in the first thermal interface material 151 and/or the second thermal interface material 152, but may particularly be included in the second thermal interface material 152 to impart fluidity to the second thermal interface material 152. In some example embodiments, the thermoplastic resin may include, for example, at least one of a polyimide resin, a polyether imide resin, a polyester imide resin, a polyamide resin, a polyether sulfone resin, a polyether ketone resin, a polyolefin resin, a polychloridevinyl resin, a phenoxy resin, a butadiene rubber, a styrene-butadiene rubber, a modified butadiene rubber, a reactivity butadiene acrylo nitrile copolymerization rubber, or an acrylate resin, but example embodiments are not limited thereto.

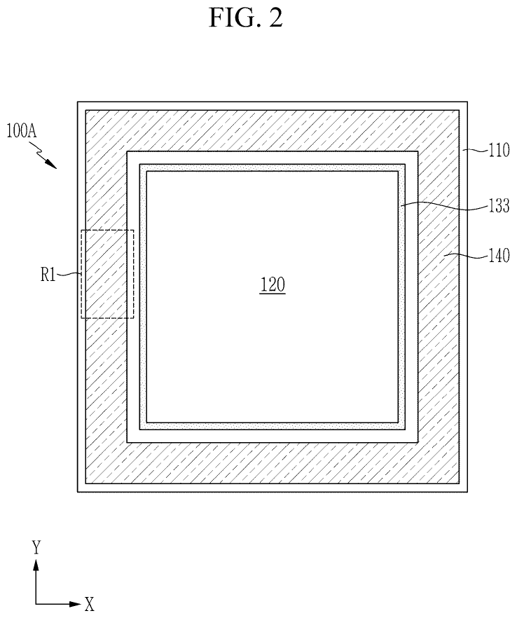

FIG. 2 is a top plan view of the semiconductor package 100A according to some example embodiments, taken along the line A-A of FIG. 1.

Referring to FIG. 2, a semiconductor package 100A according to some example embodiments may include a metal structure 140. The metal structure 140 may be disposed on an upper surface of the substrate 110. The metal structure 140 may be arranged to surround or at least partially surround the sub-semiconductor package 120. The metal structure 140 may be separated from the sub-semiconductor package 120. The metal structure 140 may extend conformally and continuously along the side surfaces of the sub-semiconductor package 120. In some example embodiments, one metal structure 140 may include or have a rectangular (for example, square) frame shape or a ring shape, but example embodiments are not limited thereto.

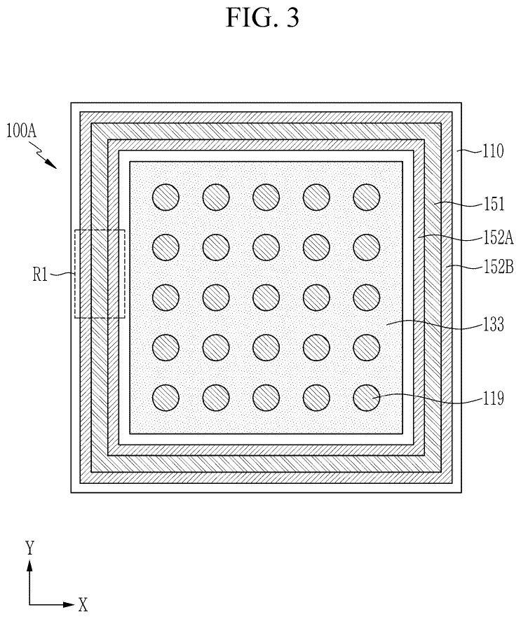

FIG. 3 is a top plan view of a semiconductor package 100A according to some example embodiments, taken along the line B-B of FIG. 1.

Referring to FIG. 3, a semiconductor package 100A according to some example embodiments may include a first thermal interface material 151 and a second thermal interface material 152. The first thermal interface material 151 and the second thermal interface material 152 may be disposed on the upper surface of the substrate 110. The first thermal interface material 151 and the second thermal interface material 152 may be arranged to surround or at least partially surround the sub-semiconductor package 120 and the underfill member 133, respectively. The first thermal interface material 151 and the second thermal interface material 152 may each be separated (for example, spaced apart) from the sub-semiconductor package 120. The first thermal interface material 151 and the second thermal interface material 152 each may extend conformally and continuously along a side surface of the sub-semiconductor package 120. With the first thermal interface material 151 as a reference, the second thermal interface material 152 may include a first portion 152A disposed on the inside of the first thermal interface material 151 and a second portion 152B disposed on the outside of the first thermal interface material 151. In some example embodiments, the first thermal interface material 151, the first portion 152A of the second thermal interface material 152, and the second portion 152B of the second thermal interface material 152 may each include a rectangular (for example, square) frame shape or a ring shape, but example embodiments are not limited thereto.

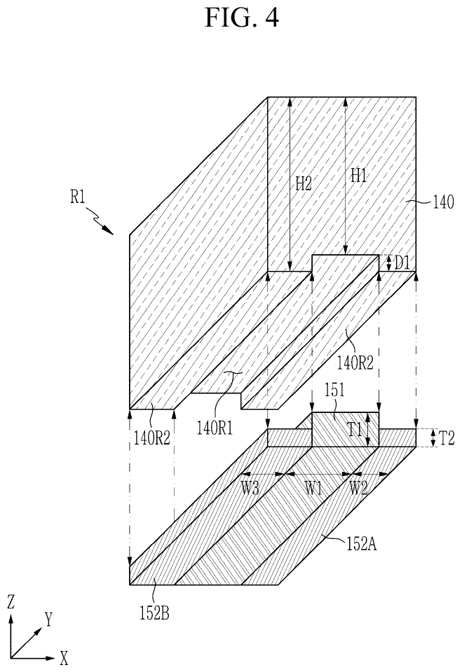

FIG. 4 is a perspective view that illustrates the metal structure 140, the first thermal interface material 151, and the second thermal interface material 152 in the region R1 of FIG. 2 and FIG. 3.

Referring to FIG. 4, a bottom surface of the metal structure 140 may include a first region 140R1 and second region(s) 140R2. The second region 140R2 may be around (for example, adjacent to and/or surrounding or at least partially surrounding) the first region 140R1. The first region 140R1 may mean a recessed region with the second region 140R2 as a reference. The first region 140R1 may be recessed from (for example, relative to or with respect to) the second region 140R2 in the Z-axis direction (vertical direction) by a depth D1. The first region 140R1 may have a shape that is conformal to the shape of the metal structure 140. The first region 140R1 may have a shape that is scaled to the shape of the metal structure 140. The first region 140R1 may have a first width W1 between the second regions 140R2. The metal structure 140 may have a first height H1 from the first region 140R1 to the upper surface. The metal structure 140 may have a second height H2 from the second region 140R2 to the upper surface. The first height H1 may be smaller than the second height H2. The sum of the depth D1 and the first height H1 may be equal to the second height H2. As described, the second thermal interface material 152 in contact with the metal structure 140 may have a relatively thin thickness, and a thickness of a portion of the metal structure 140 in contact with the second thermal interface material 152 may accordingly be relatively thick. Accordingly, the heat dissipation characteristics of the semiconductor package 100 can be improved due to the second thermal interface material 152 having a relatively thin thickness and the relatively thick metal structure 140 in contact with the second thermal interface material 152.

The first thermal interface material 151 may be disposed (for example, attached) between the first region 140R1 of the metal structure 140 and the substrate 110. The first thermal interface material 151 may have a shape corresponding to a recess shape of (for example, at least partially defined by) the first region 140R1 of the metal structure 140 (for example, the first thermal interface material 151 may have a shape corresponding to a recess at least partially defined by the recessed first region 140R1, and the regions 140R2, of the bottom surface of the metal structure 140). The first thermal interface material 151 may, for example, be attached to the recessed first region 140R1 of the metal structure 140 to fix its position, thereby improving the warpage of the semiconductor package 100. The first thermal interface material 151 may have a first thickness T1 in the Z-axis direction (vertical direction). In some example embodiments, the first thickness T1 may have, for example, a value in a range of about 80 μm to about 150 μm, but example embodiments are not limited thereto.

The second thermal interface material 152 may be disposed (for example, attached) attached between the second region(s) 140R2 of the metal structure 140 and the substrate 110. The second thermal interface material 152 may surround or at least partially surround side surfaces of the first thermal interface material 151. The second thermal interface material 152 may be divided into a first portion 152A and a second portion 152B with the first thermal interface material 151 interposed therebetween. The second thermal interface material 151 may have a second thickness T2 in the Z-axis direction (vertical direction). The second thickness T2 may be smaller than the first thickness T1. In some example embodiments, the second thickness T2 may have, for example, a value in a range of about 30 μm to about 70 μm, but example embodiments are not limited thereto.

The first thermal interface material 151 may extend with a first width W1 between the first portion 152A of the second thermal interface material 152 and the second portion 152B of the second thermal interface material 152. The first portion 152A of the second thermal interface material 152 may be extended with a second width W2. The second portion 152B of the second thermal interface material 152 may extend with a third width W3. The second width W2 of the first portion 152A of the second thermal interface material 152 may be the same as or different from the third width W3 of the second portion 152B of the second thermal interface material 152 in size. In some example embodiments, the first thermal interface material 151, the first portion 152A of the second thermal interface material 152, and the second portion 152B of the second thermal interface material 152 may be arranged such that the first width W1, the second width W2, and the third width W3 have a ratio in a range of about 1:1:1 to about 8:1:1, but example embodiments are not limited thereto. The sum of the first height H1 of the metal structure 140 and the first thickness T1 of the first thermal interface material 151 may be equal to the sum of the second height H2 of the metal structure 140 and the second thickness T2 of the second thermal interface material 152.

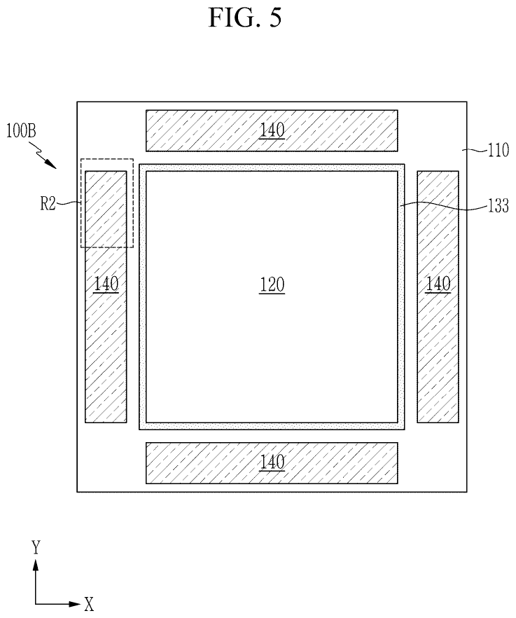

FIG. 5 is a top plan view of a semiconductor package 100B according to some example embodiments, taken along the line A-A of FIG. 1.

Referring to FIG. 5, a semiconductor package 100B according to some example embodiments may include a plurality of metal structures 140. The plurality of metal structures 140 may be disposed on the upper surface of the substrate 110. The plurality of metal structures 140 may be arranged to surround the sub-semiconductor package 120. The plurality of metal structures 140 may be separated (for example, spaced apart from) from the sub-semiconductor package 120. Each of the plurality of metal structures 140 may extend conformally and continuously along a corresponding side among the side surfaces of the sub-semiconductor package 120. In some example embodiments, each of the plurality of metal structures 140 may have, for example, an elongated shape, but example embodiments are not limited thereto.

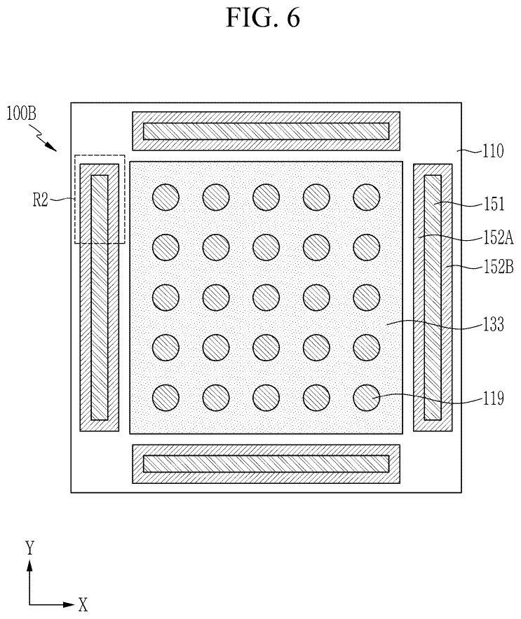

FIG. 6 is a top plan view of the semiconductor package 100B according to some example embodiments, taken along the line B-B of FIG. 1.

Referring to FIG. 6, the semiconductor package 100B according to some example embodiments may include a plurality of first thermal interface materials 151 and a plurality of second thermal interface materials 152. The plurality of first thermal interface materials 151 and the plurality of second thermal interface materials 152 may be disposed on the upper surface of the substrate 110. The plurality of first thermal interface materials 151 and the plurality of second thermal interface materials 152 may be arranged to surround or at least partially surround the sub-semiconductor package 120 and the underfill member 133, respectively. The plurality of first thermal interface materials 151 and the plurality of second thermal interface materials 152 may each be separated (for example, spaced apart from) from the sub-semiconductor package 120. Each of the plurality of first thermal interface materials 151 may extend conformally and continuously along a corresponding side among the side surfaces of the sub-semiconductor package 120. Each of the plurality of second thermal interface materials 152 may extend conformally and continuously along a corresponding side among the side surfaces of the sub-semiconductor package 120. Each of the plurality of second thermal interface materials 152 may surround or at least partially surround side surfaces of a corresponding first thermal interface material 151 among the plurality of first thermal interface materials 151. Each of the plurality of first thermal interface materials 151 may attach a first region 140R1 of a corresponding metal structure 140 among the plurality of metal structures 140 to the substrate 110. Each of the plurality of second thermal interface materials 152 may attach (for example, be used to attach) a second region 140R2 of the corresponding metal structure 140 among the plurality of metal structures 140 to the substrate 110. In some example embodiments, each of the plurality of first thermal interface materials 151 may have, for example, an elongated shape. In some example embodiments, each of the plurality of second thermal interface materials 152 may include a rectangular (for example, square) frame shape or a ring shape, but example embodiments are not limited thereto.

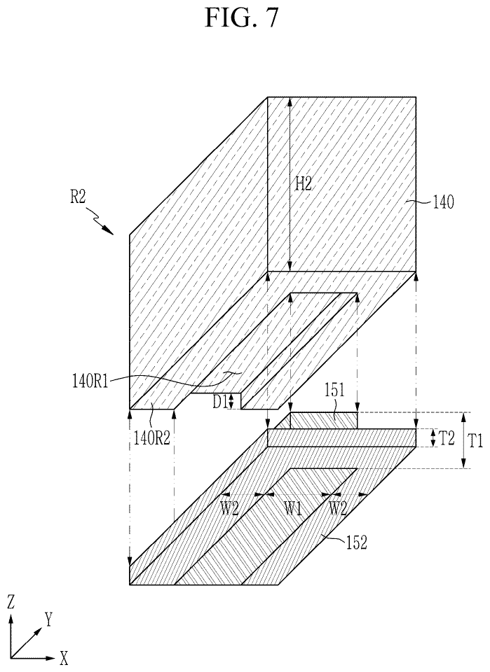

FIG. 7 is a perspective view of the metal structure 140, the first thermal interface material 151, and the second thermal interface material 152 in the region R2 of FIG. 5 and FIG. 6.

Referring to FIG. 7, a bottom surface of the metal structure 140 may include a first region 140R1 and a second region 140R2. The first region 140R1 may indicate a recessed region (for example, a region of the bottom surface of the metal structure 140 that is recessed) with reference to the second region 140R2. The first region 140R1 may be recessed from (for example, relative to or with respect to) the second region 140R2 in the Z-axis direction (vertical direction) by a depth D1. The first region 140R1 may have a shape conformal to the shape of the metal structure 140. The first region 140R1 may have a shape scaled to the shape of the metal structure 140. The first region 140R1 may have a first width W1 between the second regions 140R2. The metal structure 140 may have a first height H1 (length obtained by subtracting the depth D1 from a second height H2) from the first region 140R1 to the upper surface. The metal structure 140 may have the second height H2 from the second region 140R2 to the upper surface. The first height H1 may be smaller than the second height H2. The sum of the depth D1 and the first height H1 may be equal to the second height H2.

The first thermal interface material 151 may be disposed (for example, attached) between the first region 140R1 of the metal structure 140 and the substrate 110. The first thermal interface material 151 may have a shape corresponding to a recess shape of the first region 140R1 of the metal structure 140 (for example, the first thermal interface material 151 may have a shape corresponding to a recess at least partially defined by the recessed first region 140R1, and the regions 140R2, of the bottom surface of the metal structure 140). The first thermal interface material 151 may have a first thickness T1 in the Z-axis direction (vertical direction). In some example embodiments, the first thickness T1 may have a value in a range of about, for example, 80 μm to about 150 μm, but example embodiments are not limited thereto.

The second thermal interface material 152 may be disposed (for example, attached) between the second region 140R2 of the metal structure 140 and the substrate 110. The second thermal interface material 152 may surround or at least partially surround side surfaces of the first thermal interface material 151. The second thermal interface material 151 may have a second thickness T2 in the Z-axis direction (vertical direction). The second thickness T2 may be smaller than the first thickness T1. In some example embodiments, the second thickness T2 may have a value in a range of about, for example, 30 μm to about 70 μm, but example embodiments are not limited thereto.

The first thermal interface material 151 may extend with a first width W1. The second thermal interface material 152 may extend around the first thermal interface material 151 with a second width W2. In some example embodiments, the first width W1 and the second width W2 may have a ratio ranging from, for example, about 1:1 to about 8:1, but example embodiments are not limited thereto.

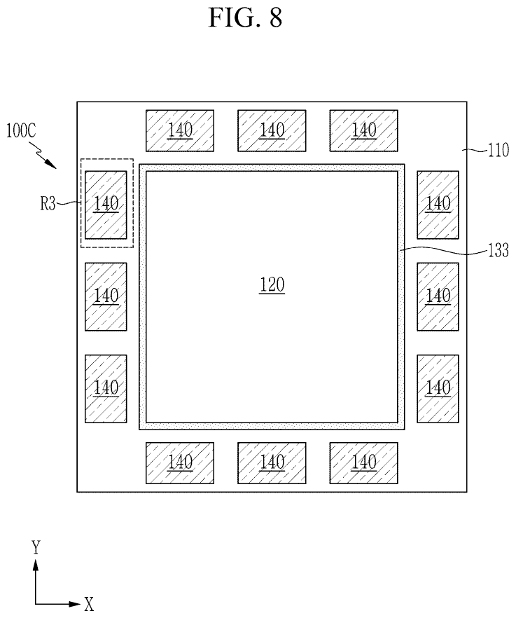

FIG. 8 is a top plan view of a semiconductor package 100C according to some example embodiments, taken along the line A-A of FIG. 1.

Referring to FIG. 8, a semiconductor package 100C according to some example embodiments may include a plurality of metal structures 140. The plurality of metal structures 140 may be disposed on the upper surface of the substrate 110. The plurality of metal structures 140 may be arranged to surround or at least partially surround the sub-semiconductor package 120. The plurality of metal structures 140 may be separated from the sub-semiconductor package 120. The plurality of metal structures 140 may be arranged along side surfaces of the sub-semiconductor package 120. In some example embodiments, each of the plurality of metal structures 140 may include a block shape.

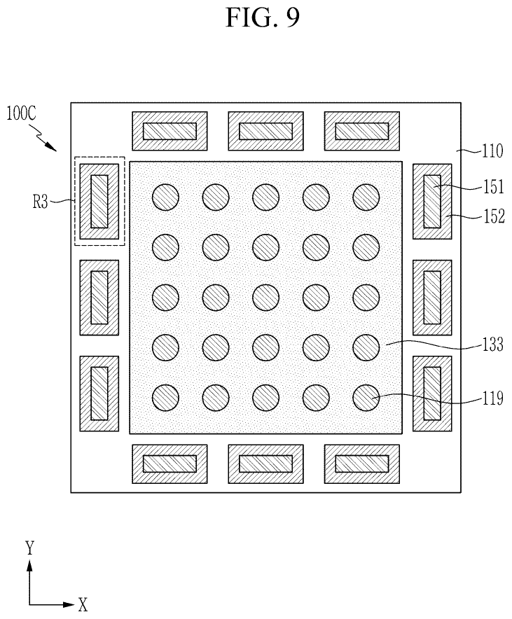

FIG. 9 is a top plan view of the semiconductor package 100C according to some example embodiments, taken along the line B-B of FIG. 1.

Referring to FIG. 9, the semiconductor package 100C according to some example embodiments may include a plurality of first thermal interface materials 151 and a plurality of second thermal interface materials 152. The plurality of first thermal interface materials 151 and the plurality of second thermal interface materials 152 may be disposed on the upper surface of the substrate 110. The plurality of first thermal interface materials 151 and the plurality of second thermal interface materials 152 may be arranged to surround the sub-semiconductor package 120 and the underfill member 133, respectively. The plurality of first thermal interface materials 151 and the plurality of second thermal interface materials 152 may each be separated from the sub-semiconductor package 120. The plurality of first thermal interface materials 151 may be arranged along side surfaces of the sub-semiconductor package 120. The plurality of second thermal interface materials 152 may be arranged along side surfaces of the sub-semiconductor package 120. Each of the plurality of second thermal interface materials 152 may surround side surfaces of a corresponding first thermal interface material 151 among the plurality of first thermal interface materials 151. Each of the plurality of first thermal interface materials 151 may attach a first region 140R1 of a corresponding metal structure 140 among the plurality of metal structures 140 to the substrate 110. Each of the plurality of second thermal interface materials 152 may attach a second region 140R2 of the corresponding metal structure 140 among the plurality of metal structures 140 to the substrate 110. In some example embodiments, each of the plurality of first thermal interface materials 151 may have a block shape or an elongated shape. In some example embodiments, each of the plurality of second thermal interface materials 152 may include a square frame shape or a ring shape.

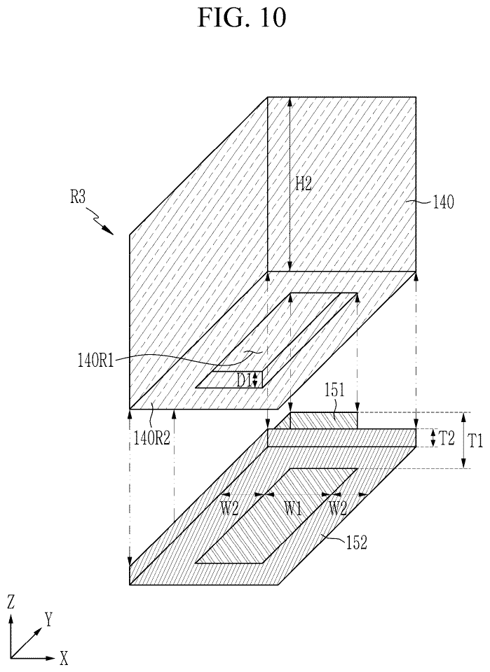

FIG. 10 is a perspective view of the metal structure 140, the first thermal interface material 151, and the second thermal interface material 152 in the region R3 of FIG. 8 and FIG. 9.

Referring to FIG. 10, a bottom surface of the metal structure 140 may include a first region 140R1 and a second region 140R2. The first region 140R1 may imply a recessed region with reference to the second region 140R2. The first region 140R1 may be recessed from (for example, with respect to or relative to) the second region 140R2 in the Z-axis direction (vertical direction) by a depth D1. The first region 140R1 may have a shape conformal to the shape of the metal structure 140. The first region 140R1 may have a shape scaled to the shape of the metal structure 140. The first region 140R1 may have a first width W1 between the second regions 140R2. The metal structure 140 may have a first height H1 (length obtained by subtracting the depth D1 from a second height H2) from the first region 140R1 to the upper surface. The metal structure 140 may have the second height H2 from the second region 140R2 to the upper surface. The first height H1 may be smaller than the second height H2. The sum of the depth D1 and the first height H1 may be equal to the second height H2.

The first thermal interface material 151 may be attached between the first region 140R1 of the metal structure 140 and the substrate 110. The first thermal interface material 151 may have a shape corresponding to a recess shape of the first region 140R1 of the metal structure 140. The first thermal interface material 151 may have a first thickness T1 in the Z-axis direction (vertical direction). In some example embodiments, the first thickness T1 may have a value in a range of about 80 μm to about 150 μm, but example embodiments are not limited thereto.

The second thermal interface material 152 may be attached between the second region 140R2 of the metal structure 140 and the substrate 110. The second thermal interface material 152 may surround side surfaces of the first thermal interface material 151. The second thermal interface material 151 may have a second thickness T2 in the Z-axis direction (vertical direction). The second thickness T2 may be smaller than the first thickness T1. In some example embodiments, the second thickness T2 may have a value in a range of about 30 μm to about 70 μm, but example embodiments are not limited thereto.

The first thermal interface material 151 may extend with a first width W1. The second thermal interface material 152 may extend around the first thermal interface material 151 with a second width W2. In some example embodiments, the first width W1 and the second width W2 may have a ratio ranging from about 1:1 to about 8:1, but example embodiments are not limited thereto.

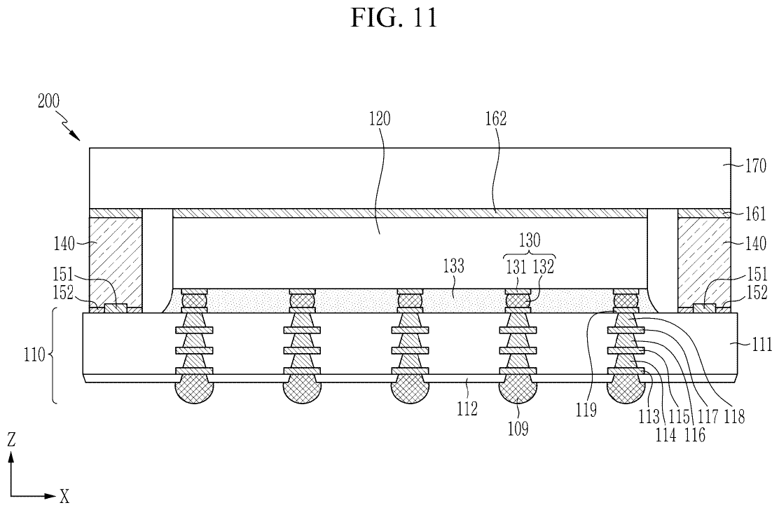

FIG. 11 is a cross-sectional view of a semiconductor package 200 according to some example embodiments.

Referring to FIG. 11, a semiconductor package 200 may include a heat dissipation structure 170. A heat dissipation structure 170 may be disposed on the metal structure 140. The heat dissipation structure 170 may be attached to the metal structure 140 by a third thermal interface material 161. The heat dissipation structure 170 may be integrally formed with the metal structure 140 without the third thermal interface material 161. The heat dissipation structure 170 may be disposed on the sub-semiconductor package 120. The heat dissipation structure 170 may be attached on the sub-semiconductor package 120 by the fourth thermal interface material 162. For the third thermal interface material 161 and fourth thermal interface material 161, the same description as for first thermal interface material 151 may be applied.

The heat dissipation structure 170 may be thermally connected to the sub-semiconductor package 120 and to the metal structure 140. Heat generated in the sub-semiconductor package 120 may be transmitted directly to the heat dissipation structure 170, or may be transmitted to the heat dissipation structure 170 via the metal structure 140 through the substrate 110. The heat dissipation structure 170 may dissipate the received heat to the outside of the semiconductor package 200. In some example embodiments, the heat dissipation structure 170 may include a heat slug, a heat sink, or a heat spreader. In some example embodiments, the heat dissipation structure 170 may include a conductive material having higher thermal conductivity. In some example embodiments, the heat dissipation structure 170 may include at least one of copper, aluminum, silver, tin, gold, nickel, lead, titanium, and alloys thereof.

Except for the above, the contents of the semiconductor package 200 of FIG. 11 may be applied to the contents described for FIG. 1 to FIG. 10.

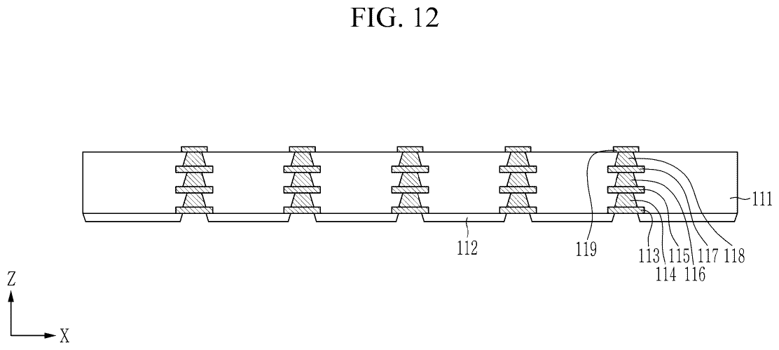

FIG. 12 to FIG. 19 are cross-sectional views provided for description of methods for manufacturing the semiconductor package 100 of FIG. 1. Methods for manufacturing the semiconductor package 100 of FIG. 1, which will be descried with reference to FIG. 12 to FIG. 19 can be equally applied to a method for manufacturing a semiconductor package 200 of FIG. 11.

FIG. 12 is a cross-sectional view of providing a substrate base 111.

Referring to FIG. 12, a substrate base 111 where wiring pattern structures 113 to 119 are formed may be provided.

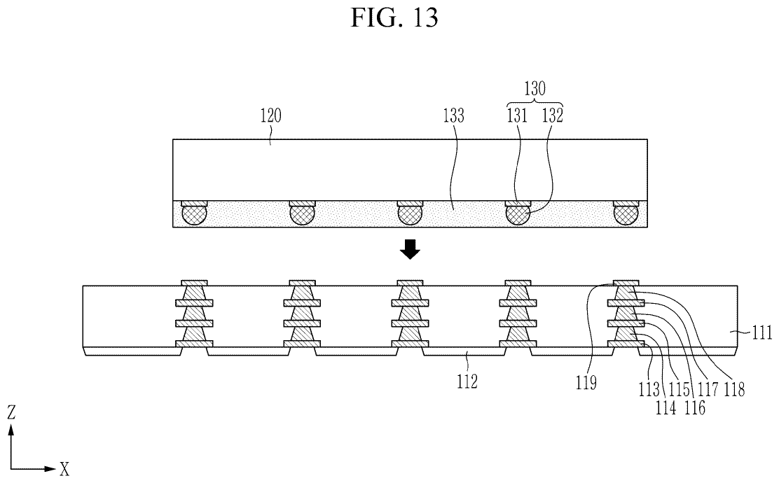

FIG. 13 is a cross-sectional view illustrating mounting the sub-semiconductor package 120 on the substrate 110.

Referring to FIG. 13, the sub-semiconductor package 120 may be mounted on the substrate base 111. Prior to mounting, the underfill member 133 may be attached to the bottom surface of the sub-semiconductor package 120, and the bump structures 130 may be surrounded by the underfill member 133. The sub-semiconductor package 120 may be bonded on the substrate base 111 by, for example, a thermal compression (TC) process, but example embodiments are not limited thereto. The solders 132 may be bonded to the bonding pads 119 by, for example, the thermal compression (TC) process.

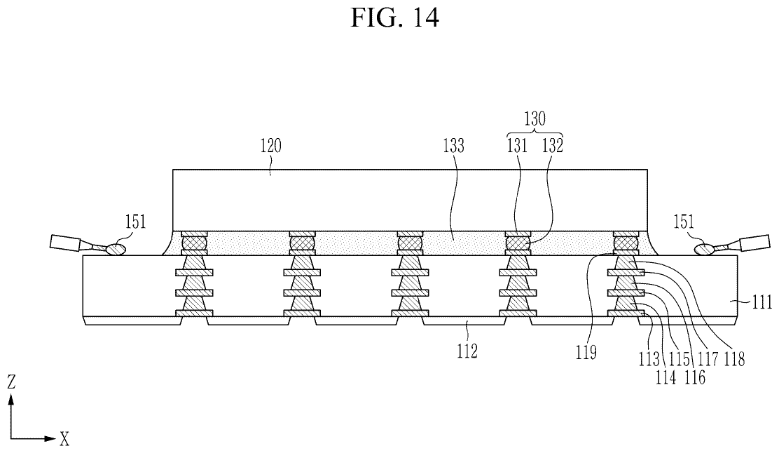

FIG. 14 is a cross-sectional view of applying the first thermal interface material 151 on the substrate 110.

Referring to FIG. 14, the first thermal interface material 151 may be applied to a region on the substrate 110 where the first region 140R1 of the metal structure 140 is to be disposed. In some example embodiments, the first thermal interface material 151 may include, for example, a thermal paste, a thermal pad, a phase change material (PCM), a metal material, and/or grease, but example embodiments are not limited thereto.

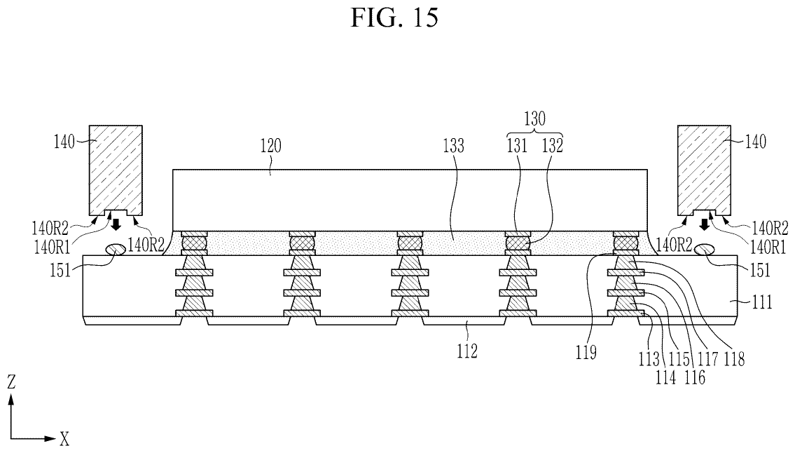

FIG. 15 is a cross-sectional view of arranging the metal structure 140 on the substrate 110.

Referring to FIG. 15, the metal structure 140 may be attached on the substrate 110. The first region 140R1 of the metal structure 140 may be attached to the substrate 110 by the first thermal interface material 151.

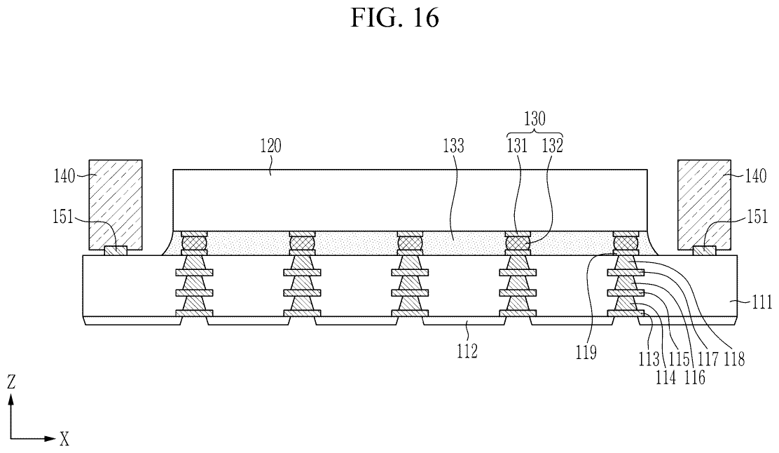

FIG. 16 is a cross-sectional view of curing the first thermal interface material 151.

Referring to FIG. 16, the first thermal interface material 151 is cured, and the metal structure 140 and the substrate 110 may be physically, mechanically, and/or thermally bonded.

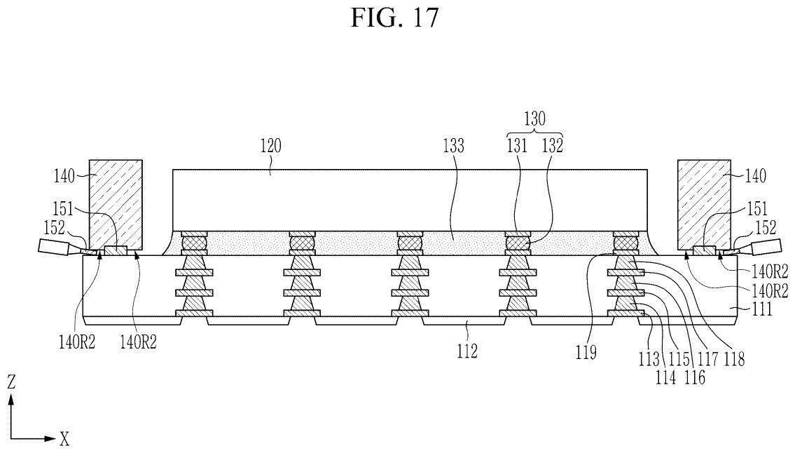

FIG. 17 is a cross-sectional view of inserting the second thermal interface material 152 between the metal structure 140 and the substrate 110.

Referring to FIG. 17, the second thermal interface material 152 may be injected between an edge of the second region 140R2 of the metal structure 140 and the substrate 110. In some example embodiments, the second thermal interface material 152 may include, for example, a thermal paste, but example embodiments are not limited thereto.

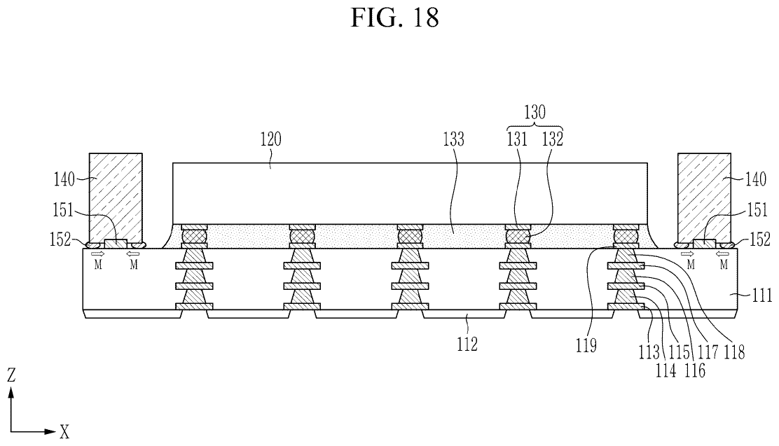

FIG. 18 is a cross-sectional view of moving of the second thermal interface material 152.

Referring to FIG. 18, the second thermal interface material 152 may move inwardly (indicated by arrows “M”) toward the position of the first thermal interface material 151 by capillary action. The second thermal interface material 152 fills (for example, moves to fill or substantially fill) an empty space between (for example, defined between) the second region 140R2 of the metal structure 140 and the substrate 110, and may be in (for example, come into) contact with the first thermal interface material 152. A process of filling the empty space between the second region 140R2 of the metal structure 140 and the substrate 110 with the second thermal interface material 152 utilizes capillary action phenomena, and accordingly the second thermal interface material 152 may have a characteristic of greater fluidity than the first thermal interface material 152. The first thermal interface material 151 may have first lowest viscosity. The second thermal interface material 152 may have the second lowest viscosity. The second lowest viscosity may be less than the first lowest viscosity. Since the area of the space between the substrate 110 and the metal structure 140 that is not filled by the first thermal interface material 151 may be specified, it is possible to inject an exact (for example, substantially exact) amount of the second thermal interface material 152 to match (for example, fill or substantially fill) the area of the space between the substrate 110 and the metal structure 140. Accordingly, the adhesion reliability of the metal structure 140 to the substrate 110 can be improved, and the warpage of the semiconductor package 100 can be improved.

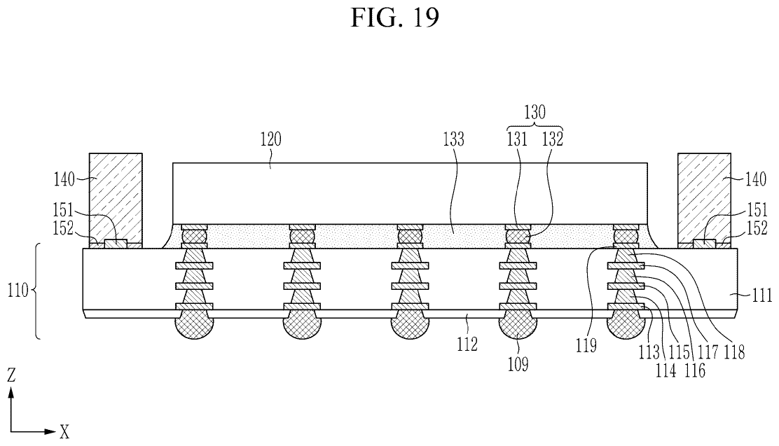

FIG. 19 is a cross-sectional view of curing the second thermal interface material 152.

Referring to FIG. 19, the second thermal interface material 152 is cured and the metal structure 140 and the substrate 110 may be physically, mechanically, and/or thermally bonded. After that, the connection members 109 may be formed below the substrate base 111. In some example embodiments, the connection members 109 may include a bump and/or a solder ball. In some example embodiments, the connection members 109 each may include at least one of tin, silver, lead, nickel, copper, and any alloys thereof, but example embodiments are not limited thereto. In another embodiment, a semiconductor package 100 including fewer or more connecting members may be included within the scope of the present disclosure.

While inventive concepts have been described in connection with various example embodiments, it is to be understood that the inventive concepts are not limited to the described example embodiments. On the contrary, they are intended to cover various modifications and equivalent arrangements included within the spirit and scope of the appended claims.

What is claimed is:

1. A semiconductor package, comprising:
a substrate;
a sub-semiconductor package on the substrate;
a metal structure on the substrate and adjacent to the sub-semiconductor package, a bottom surface of the metal structure including a first region and a second region at least partially surrounding the first region, the first region being recessed from the second region;
a first thermal interface material between the substrate and the first region; and
a second thermal interface material between the substrate and the second region.

2. The semiconductor package of claim 1, wherein each of the first thermal interface material and the second thermal interface material comprises a thermosetting resin and a conductive filler.

3. The semiconductor package of claim 2, wherein the first thermal interface material and the second thermal interface material are different from each other with respect to at least one of
a material of the thermosetting resin,
a material of the conductive filler,
a size of the conductive filler,
or a content of the conductive filler.

4. The semiconductor package of claim 2, wherein each of the first thermal interface material and the second thermal interface material further comprises at least one of a hardener, a catalyst, or a thermoplastic resin.

5. The semiconductor package of claim 1, wherein the first thermal interface material comprises a first conductive filler, the second thermal interface material comprises a second conductive filler, and the first conductive filler and the second conductive filler comprise a same material.

6. The semiconductor package of claim 5, wherein the first conductive filler has a first content, the second conductive filler has a second content, and the first content is greater than the second content.

7. The semiconductor package of claim 5, wherein the first conductive filler has a first size, the second conductive filler has a second size, and the first size is greater than the second size.

8. The semiconductor package of claim 1, wherein the first thermal interface material has a first thermal conductivity, the second thermal interface material has a second thermal conductivity, and the first thermal conductivity is greater than the second thermal conductivity.

9. The semiconductor package of claim 1, wherein the first thermal interface material has a first thermal resistance, the second thermal interface material has a second thermal resistance, and the first thermal resistance is less than the second thermal resistance.

10. The semiconductor package of claim 1, wherein the second thermal interface material at least partially surrounds side surfaces of the first thermal interface material.

11. The semiconductor package of claim 1, wherein the metal structure comprises at least one of a heat slug or a stiffener.

12. The semiconductor package of claim 1, further comprising a heat dissipation structure that is on the metal structure and on the sub-semiconductor package.

13. The semiconductor package of claim 1, wherein the metal structure is electrically isolated from the substrate and from the sub-semiconductor package.

14. The semiconductor package of claim 1, wherein the metal structure is thermally connected to the substrate.

15. A semiconductor package, comprising:
a substrate;
a sub-semiconductor package on the substrate;
a plurality of metal structures on the substrate and at least partially surrounding side surfaces of the sub-semiconductor package, a bottom surface of each of the plurality of metal structures including a first region and a second region at least partially surrounding the first region, the first region being recessed from the second region;
a plurality of first thermal interface materials, each of the plurality of first thermal interface materials attaching the first region of a corresponding metal structure among the plurality of metal structures to the substrate and having a first thickness in a vertical direction; and
a plurality of second thermal interface materials, each of the plurality of second thermal interface materials attaching the second region of a corresponding metal structure among the plurality of metal structures to the substrate and having a second thickness that is smaller than the first thickness in the vertical direction.

16. The semiconductor package of claim 15, wherein each of the plurality of metal structures conformally extends along a corresponding one of the side surfaces of the sub-semiconductor package.

17. The semiconductor package of claim 15, wherein the plurality of metal structures are arranged along the side surfaces of the sub-semiconductor package.

18. A semiconductor package manufacturing method, comprising:
mounting a sub-semiconductor package on a substrate;
applying a first thermal interface material on the substrate and adjacent to the sub-semiconductor package;
attaching a metal structure to the first thermal interface material, a bottom surface of the metal structure including a first region and a second region at least partially surrounding the first region, the first region being recessed from the second region, the first thermal interface material being attached to the first region; and
inserting a second thermal interface material between the substrate and the second region of the metal structure.

19. The semiconductor package manufacturing method of claim 18, wherein the first thermal interface material has a first lowest viscosity, the second thermal interface material has a second lowest viscosity, and the second lowest viscosity is less than the first lowest viscosity.

20. The semiconductor package manufacturing method of claim 18, wherein the inserting the second thermal interface material between the substrate and the second region of the metal structure comprises:
injecting the second thermal interface material between the substrate and the second region of the metal structure; and
moving of the second thermal interface material by capillary action to contact the first thermal interface material.
